(19) United States
(12) Patent Application Publication
(10) Pub. No.: US 2011/0217653 A1
(43) Pub. Date: Sep. 8, 2011

(54) INTERMEDIATE TRANSFER BELT FOR IMAGE FORMING APPARATUS, METHOD OF PREPARING THE BELT, AND IMAGE FORMING METHOD AND APPARATUS USING THE BELT

(76) Inventors: Akira Izutani, Osaka-fu (JP); Makoto Matsushita, Osaka-fu (JP)

(21) Appl. No.: 13/020,459

(22) Filed: Feb. 3, 2011

(30) Foreign Application Priority Data
Mar. 2, 2010 (JP) 2010-045687

(51) Int. Cl. G03G 15/20; H01B 1/12; H01B 1/24; H01B 1/22; G03G 13/20; H01J 37/30; B82Y 30/00

(52) U.S. Cl. 430/124.1; 399/308; 252/500; 252/511; 252/519.33; 252/513; 252/512; 264/470; 977/773

(57) ABSTRACT

A belt member for intermediate transfer, including a crosslinked product of a thermoplastic resin; and an electroconductive particulate material, wherein the belt member satisfies the following formulae (I) and (ii):

6≦log(ρv200)≦10 (i)

0≦log(ρv10)−log(ρv1,000)≦2 (ii)

wherein ρv200, ρv10 and ρv1,000 represent volume resistivities when the belt member is applied with biases of 200 V, 10 V and 1,000 V, respectively.

### BACKGROUND OF THE INVENTION

1. Field of the Invention

The present invention relates to an intermediate transfer belt for an image forming apparatus using electrophotographic methods or electrostatic printing methods, such as copiers, printers, and facsimiles, a method of preparing the belt, and image forming technologies using the belt, and more particularly, to an intermediate transfer belt for an image forming apparatus, having desired electrical properties and stress resistance even when a thermoplastic resin is used therefor, a method of preparing the belt, and an image forming method and apparatus using the belt.

2. Description of the Background Art

In electrophotographic image forming apparatuses, a developed toner image is intermediately transferred onto a belt-shaped intermediate transfer medium initially, and then secondarily transferred onto a final transfer medium such as paper. Particularly with recent full-color electrophotographic image forming apparatus, developed yellow, magenta, cyan and black images are superimposed on an intermediate transfer medium initially, and then transferred together onto the final transfer medium. Therefore, the electrophotographic image forming apparatus is required to produce full-color and black (monochrome) images on final transfer media such as papers having different thickness, sizes, materials, and electrostatic properties.

To accommodate such variety, thermoplastic and thermosetting resins are used for forming the intermediate transfer belt. Typically, resistance controlling agents, e.g., electroconductive particulate materials such as carbon black, particulate metals and metal suboxides, and ion conductive materials such as hydrocarbon ammonium salts including a hydrocarbon group, are added.

Japanese published unexamined application No. 2009-25625 discloses a method of dispersing electroconductive materials such as carbon black in a low-viscosity solution including thermosetting resin precursors such as polyamide and polyamideimide.

However, reduction of CO₂ emissions has come to be more desired recently. The thermosetting resins require use of an organic solvent, and cannot continuously be produced or recycled, which imposes a large CO₂ emissions burden on the environment.

On the other hand, Japanese published unexamined applications Nos. 2007-65587 and 2008-239947, and Japanese Patent No. 3821600 disclose a method of using a thermoplastic resin with a smaller CO₂ emission footprint the thermosetting resins for forming an electroconductive endless belt, which can continuously be produced, reduce environmental burden when produced, and are easily recyclable.

However, electroconductive particulate materials such as carbon black are not as easily uniformly dispersed in an electroconductive belt formed of a thermoplastic resin less as with that formed of a thermosetting resin.

For the purpose of improving dispersibility of an electroconductive material such as carbon black in a thermoplastic resin, caloric and shearing energy can be increased to uniformly and finely disperse the electroconductive material. However, large amounts of caloric and shearing energy cut a polymer chain of the thermoplastic resin and make the electroconductive particulate material enter a crystal area thereof. This lowers elasticity and a glass transition temperature of a semi-conductive material, resulting in quality problems such as belt flexure and creep when installed in an image forming apparatus.

At present, an electroconductive belt including thermoplastic resin and electroconductive material having satisfactory voltage dependency (electrical properties) without quality problems such as belt flexure and creep is not available.

There is another consideration as well. That is, because the recording media (typically paper) to be transferred have different thicknesses and widths, a secondary transfer voltage needs controlling every time in the secondary transfer process using an intermediate transfer belt. However, when the intermediate transfer belt material has a volume resistivity largely dependent on voltage, it is difficult to control the second transfer voltage. It has only recently been understood that the intermediate transfer belt material has a volume resistivity largely dependent on voltage because the electroconductive particulate material such as carbon black is not uniformly dispersed in the resin.

Namely, when the electroconductive particulate material such as carbon black is not uniformly dispersed in the resin, the resistivity largely depends on the applied bias. This is a particularly serious problem for all-purpose image forming apparatuses capable of using various types of transfer media such as paper.

Therefore, to decrease dependency of the resistivity of the intermediate transfer belt on the applied bias and improve the resultant image quality, it is highly effective that the electroconductive particulate material such as carbon black is more uniformly dispersed in the resin.

However, when an electroconductive material is added to a thermoplastic resin to control resistivity, it is not at all simple both to limit the volume resistivity to an extremely narrow range and at the same time decrease dependency of the resistivity on the applied bias.

For these reasons, a need exists for an intermediate transfer belt having improved electrical properties in which an electroconductive material such as carbon black is finely and uniformly dispersed without deterioration of thermal and mechanical properties.

### SUMMARY OF THE INVENTION

Accordingly, an object of the present invention is to provide an intermediate transfer belt having improved electrical properties in which an electroconductive material such as carbon black is finely and uniformly dispersed without deterioration of thermal and mechanical properties.

Another object of the present invention is to provide a method of preparing the belt.

A further object of the present invention is to provide an image forming method using the belt.

Another object of the present invention is to provide an image forming apparatus using the belt.

These objects and other objects of the present invention, either individually or collectively, have been satisfied by the discovery of a belt member for intermediate transfer, comprising:

a crosslinked product of a thermoplastic resin; and

an electroconductive particulate material,

wherein the belt member satisfies the following formulae (i) and (ii):

6≦log(ρv200)≦10 (i)

0≦log(ρv10)−log(ρv1,000)≦2 (ii)

wherein ρv200, ρv10 and ρv1,000 represent volume resistivities when the belt member is applied with biases of 200 V, 10 V and 1,000 V, respectively.

These and other objects, features and advantages of the present invention will become apparent upon consideration of the following description of the preferred embodiments of the present invention taken in conjunction with the accompanying drawings.

### BRIEF DESCRIPTION OF THE DRAWINGS

Various other objects, features and attendant advantages of the present invention will be more fully appreciated as the same becomes better understood from the detailed description when considered in connection with the accompanying drawings in which like reference characters designate like corresponding parts throughout and wherein:

FIG. 1 is a diagram specifically showing the resistivity (Log) of an intermediate transfer belt scarcely has dependency on the content of an electroconductive particulate material in a thermoplastic resin, and the content thereof is difficult to control the electrical properties required for the intermediate transfer belt (Log p of from 6 to 10) because of a rapid change in slope;

FIG. 2 is a diagram explaining cases where the electroconductive particulate material has good dispersibility and poor dispersibility;

FIG. 3 is a schematic view illustrating an embodiment of the image forming apparatus of the present invention;

FIG. 4 is a diagram showing a hysteresis loop of the measurement of mechanical properties in the present invention;

FIG. 5 is a STEM photograph showing a case where the electroconductive particulate material has good dispersibility;

FIG. 6 is a STEM photograph showing another case where the electroconductive particulate material has good dispersibility; and

FIG. 7 is a STEM photograph showing a case where the electroconductive particulate material has poor dispersibility.

### DETAILED DESCRIPTION OF THE INVENTION

The present invention provides an intermediate transfer belt having improved electrical properties in which an electroconductive material such as carbon black is finely and uniformly dispersed without deterioration of thermal and mechanical properties.

More particularly, the present invention relates to a belt member for intermediate transfer, comprising:

a crosslinked product of a thermoplastic resin; and

an electroconductive particulate material,

wherein the belt member satisfies the following formulae (i) and (ii):

6≦log(ρv200)≦10 (i)

0≦log(ρv10)−log(ρv1,000)≦2 (ii)

wherein ρv200, ρv10 and ρv1,000 represent volume resistivities when the belt member is applied with biases of 200 V, 10 V and 1,000 V, respectively.

First, difficulty of controlling the volume resistivity in a specific narrow range and decreasing dependency of the resistivity on an applied bias at the same time will be explained.

It is very difficult to satisfy the formulae (i) and (ii) when controlling the resistivity by adding an electroconductive material to a thermoplastic resin. This can be explained as a percolation model.

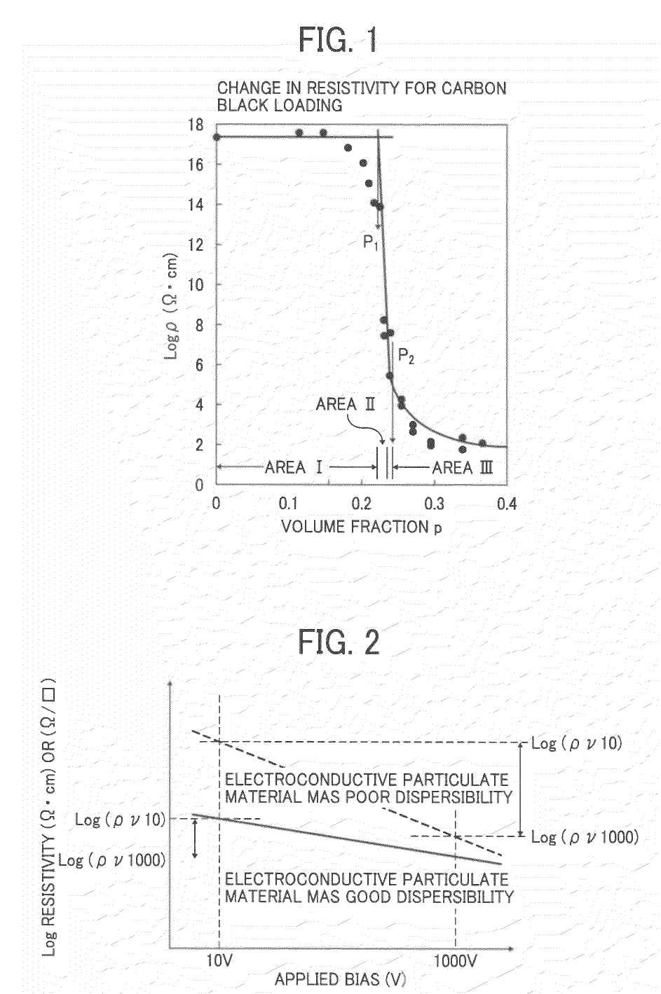

FIG. 1 is a diagram in which an x-axis is a content of an electroconductive particulate material in a thermoplastic resin, and y-axis is resistivity (Log). The content thereof is difficult to control the electrical properties required for the intermediate transfer belt (Log ρ of from 6 to 10) because of a rapid change in slope.

The slope is larger than that of a thermosetting resin, and it is difficult to control properties when using a thermoplastic resin as a material.

One of methods of controlling the slope of threshold is uniformly and finely dispersing an electroconductive material in a resin. The electroconductive material can uniformly and finely be dispersed in a thermoplastic resin by a kneader at a constant temperature and a higher power for a long time.

However, it is well known that the molecular chain of a thermoplastic resin is cut when kneaded by a kneader at a constant temperature and a higher power for a long time and the mechanical properties thereof deteriorates, and the method has not been selected. In the present invention, a meltable resin having properly a high viscosity is kneaded (the resin is repeatedly extended and folded), the association state of an electroconductive material somewhat firmly held therein is rapidly released with the extension of the resin, and the resin is subjected to an electron beam cross-linking to improve the electrical properties thereof and prevent deterioration mechanical properties thereof after kneaded and extruded. An electroconductive material cannot be firmly held in a thin resin material having a low viscosity, which is kneaded at an excessively high temperature, and therefore, the association state thereof cannot efficiently be released. Not only heat energy but also mechanical energy is regarded as more important, and the electron beam irradiation complements quality problems such as belt flexure and creep.

The electroconductive particulate material of the present invention, such as carbon black preferably has a primary average particle diameter not greater than 200 nm, more preferably from 3 to 150 nm, and most preferably from 5 to 50 nm. Typically, dozens to thousands or ten thousands of such ultrafine particles are associated with each other to be secondarily particulated for discharging an energy (being stabilized) coming from its high activity level. In the present invention, the association state is released in the kneading process and the electroconductive particulate material is thought to disperse well. The uniform dispersion state required to decrease the dependency of the resistivity on an applied bias in the present invention is that the electroconductive particulate material having a primary particle diameter of from 3 to 150 nm, and more preferably from 5 to 50 nm is dispersed in a resin when the belt material is observed with a STEM picture. The secondary particles which are the associated primary particles remain, but the number thereof is not greater than that of the primary particles and the size thereof is about that of 9 or less primary particles associated.

FIG. 2 is a diagram for explaining a good dispersibility and a poor dispersibility of an electroconductive particulate material, in which a solid line shows that an electroconductive particulate material such as carbon black is finely and uniformly dispersed in a resin; and a chain line shows that an electroconductive particulate material such as carbon black is not finely and uniformly dispersed in a resin. The resistivity of the electroconductive particulate material less depends on an applied bias when uniformly dispersed.

Japanese published unexamined applications Nos. 2007-65587 and 2008-239947 do not disclose the dispersibility of an electroconductive particulate material such as carbon black for controlling important electrical properties as an intermediate transfer belt. Namely, the electrical properties thereof have problems. An insufficiently dispersed electroconductive particulate material affects image quality.

Japanese Patent No, 3821600 discloses a range of an important electrical property (volume resistivity), but does not disclose the dependency thereof on an applied bias. Particularly when an intermediate transfer belt has a volume resistivity largely dependent on a bias in a second transfer, media such as small-size papers and papers the both side of which are printed largely vary their resistivity in a nip and a sufficient transfer electric field is not formed, resulting in deterioration of image quality such as poor transfer.

The intermediate transfer belt for use in the electrophotographic image forming apparatus of the present invention needs to have a volume resistivity in a range of (i) 6≦log(ρv200)≦10. When log(ρv200)<6, an electric field at a transfer nip is not stable, resulting in discharge phenomena before and after or at the transfer nip.

When log(ρv200)>10, the surface potential does not reduce, resulting in deterioration of image quality such as image memory.

The image forming method using an intermediate transfer method of the present invention includes a first transfer process transferring a toner image from an image bearer onto an intermediate transfer belt and a second transfer process transferring a toner image onto a paper from the intermediate transfer. Particularly in the second transfer process, the second transfer bias needs controlling every time when papers a toner image is transferred on because of having different thickness and width. The second transfer bias is difficult to control when the volume resistivity of the intermediate transfer belt largely depends on a bias.

Further, after kneaded, an electron beam is irradiated to cut a molecular chain of the thermoplastic resin, and a radical electron is generated to be combined with the molecular chain to form the thermoplastic resin having a crosslinked structure.

There are crosslinked polymers preferentially crosslinked and collapsing polymers in which a main chain is preferentially cut when irradiated with an electron beam. Whether crosslinked or collapsing has the following experimental relation dependent on a molecular structure, and dominated by an electron state of a carbon atom having a substituent. Specific examples of the crosslinked polymers include polyethylene, polystyrene, polypropylene, polyvinylidenefluoride, polymethylacrylate, polyvinylchloride, polybutadiene, natural rubbers, polyvinylalcohol, polyamide, etc. Specific examples of the collapsing polymers include polytetrafluoroethylene, poly-α-methylstyrene, polyisobutylene, polyacryloamide, polymethylmethacrylate, polycarbonate, polyoxymethylene, polyalanine, cellulose, etc.

A crosslinked resin increases in melt viscosity, and when crosslinked before melted and extruded, the requisite shearing energy cannot be obtained to uniformly disperse an electroconductive material.

An electroconductive material such as carbon black dispersed in a thermoplastic resin by a mechanical shearing force is excluded from a crystal region and resumes aggregating after kneaded and extruded as the resin molecule crystallizes. After extruded, an electron beam is irradiated on the resin a higher temperature than a temperature (Tg) at which the resin starts crystallizing to crosslink the resin. Thus, the crystallization of the resin can be prevented and the uniformity of the electroconductive material can be maintained. In addition, the elasticity and anti-creep of the belt can be improved.

When a resin is irradiated with an electron beam, a radical electron is formed on a polymer chain, and the radical electron is a starting point of the crosslinking reaction process. The resin is not fully crosslinked when not sufficiently irradiated with the electron beam. When irradiated too much, the polymer chain is cut more quickly than the crosslinking reaction, resulting in deterioration of the thermoplastic resin. The thermoplastic resin is preferably irradiated in an amount of from 10 kGy to 1,000 kGy (1 Gy=1 J/kg) at an accelerating voltage of from 100 kV to 1,000 kV to generate a radical forming a crosslinked structure.

Some thermoplastic resins are difficult to bring to a crosslinking reaction. Therefore, a crosslinker is preferably used to complement the crosslinking reaction. The crosslinker is preferably a member selected from the group consisting of triallylisocyanurate, triallylcyanurate, trimethallylisocyanurate, diallylmonoglycidylisocyanurate and their mixtures.

Specific examples of the thermoplastic resins used for intermediate transfer belt materials include polyethylene; polypropylene; polystyrene; thermoplastic polyamide (PA); acrylonitrile-butadiene-styrene (ABS) resins; thermoplastic polyacetal (POM); thermoplastic polyarylate (PAR); thermoplastic polycarbonate (PC); thermoplastic urethane; polyethylenenaphthalate (PEN) resins; polybutylenenaphthalate (PBN) resins; polyalkyleneterephthalate resins such as polyethyleneterephthalate (PET) resins, glycol-modified PET (PETG) resins and polybutyleneterephthalate (PBT) resins; polymer blends such as two or more of polyalkylenenaphthalate resins or the polyalkyleneterephthalate resins; and polymer blends including one of the polyalkylenenaphthalate resins or the polyalkyleneterephthalate resins and polyester elastomers, polycarbonate resins (PC), polycyclohexylene-dimethylene-terephthalate (PCT) resins or glycol-modified PCT (PCTG) resins, etc. Specific examples of the polyester elastomers include, but are not limited to, polyester-polyester types using polyester in a hard segment and a soft segment; and polyether-polyether types using polyether in a hard segment and a soft segment.

Specific examples of fluorine-containing resins include, but are not limited to, polyvinylidenefluoride (PVDF), vinylidenefluoride-tetrafluoroethylene copolymers [Poly(VdF-TFE)], ethylene-tetrafluoroethylene copolymers (ETFE), polychlorotrifluoroethylene (PCTFE), tetrafluoroethylene-hexafluoropropylene copolymers (FEP), tetrafluoroethylene-perfluoroalkylvinylether copolymers (PFA), etc.

The intermediate transfer belt needs to have a volume resistivity in a semiconductive range as one of its electrical properties, preferably of from 10⁶ to 10¹⁰ Ω·cm, and more preferably from 10⁶ to 10⁸ Ω·cm. The surface resistivity is preferably from 10⁶ to 10¹⁰ Ω·cm. Further, the surface resistivity is preferably not less than the volume resistivity.

The volume resistivity and surface resistivity are less than the minimum, a toner electrostatically adheres to the belt more firmly, resulting in lowering the second transfer efficiency. When greater than the maximum, a charge induced by an applied transfer bias on the belt is not discharged, resulting in image quality problems such as image memory.

When the volume resistivity is greater than the surface resistivity, the resultant image edge blurs without sharpness.

In order to control the volume resistivity and surface resistivity of the resin belt, an electronically conductive material is added therein. An electronically conductive material is preferably used in an intermediate transfer belt in consideration of durability and stability of usage environment. In the present invention, an ionic conductive material can be used together with the electronically conductive material in a small amount. The ionic conductive material can be expected to act as a dispersant for the electronically conductive material.

The electronically conductive particulate material is dispersed in a thermoplastic resin to form a semiconductive resin material. However, the resistivity depends on an applied bias. When it depends on the applied bias too much, the resultant images deteriorate such as rough solid images.

In the present invention, the following relation is satisfied:

0≦log(ρv10)−log(ρv1,000)≦2

wherein ρv10 and ρv1,000 represent volume resistivities when the belt member is applied with biases of 10 V and 1,000 V, respectively.

The electroconductive particulate material such as carbon black is dispersed in a heated and melted thermoplastic resin. The electroconductive particulate material can finely and uniformly be dispersed when applied with more calorie and shearing energy. However, large amounts of calorie and shearing energy cut a polymer chain of the thermoplastic resin and make the electroconductive particulate material enter a crystal area thereof. This degrades elasticity and glass transition temperature of a semi-conductive material.

The crosslinkers are not particularly limited, if they can perform crosslinking reactions when irradiated with an electron beam. Acrylicmultifunctional monomers are preferably used. Specific examples of the acrylic multifunctional monomers include triallylisocyanurate, triallylcyanurate, trimethallylisocyanurate, diallylmonoglycidylisocyanurate (DA-MGIC), etc. Among these, DA-MGIC is most preferably used because of exerting a crosslinking effect in a small amount. Specific examples of the other crosslinkers include multifunctional (meth)acrylic monomers such as diethyleneglycoldi(meth)acrylate, dipentaerythritolhexa(meth)acrylate, dipentaerythritolmonohydroxypenta(meth)acrylate, pentaerthritoltri(meth)acrylate, pentaerthritoltetra(meth)acrylate, polyethyleneglycoldi(meth)acrylate, trimethylolpropanetri(meth)acrylate, tris(acryloxyethyl)isocyanurate, tris(methacryloxyethyl)isocyanurate and their mixtures. These can be used alone or in combination. The crosslinker is preferably included in an amount of from 0.5 to 15 parts by weight, and more preferably from 2 to 10 parts by weight per 100 parts by weight of the resin. When the amount is too much, the resultant belt has poor appearance and low strength.

Electron conductivizers are not particularly limited, and known electron conductivizers can be used. Specific examples thereof include electroconductive carbons such as ketjen black and acetylene black; carbons for rubber such as SAF, ISAF, HAF, FEF, GPF, SRF, FT and MT; oxidatively-treated carbons for color ink; pyrolyzed carbons; natural graphite; artificial graphite; metals and metal oxides such as antimony-doped tin oxide, titaniumoxide, zinc oxide, nickel, copper, silver and germanium; electroconductive polymers such as polyaniline, polypyrrole and polyacetylene; electroconductive whiskers such as carbon whiskers, graphite whiskers, titanium carbonate whiskers, electroconductive kalium titanate whiskers, electroconductive barium titanate whiskers, electroconductive titanium oxide whiskers and electroconductive zinc oxide whiskers.

Specific examples of ionic conductivizers include perchlorates such as tetraethylammonium, tetrabutylammonium, dodecyltrimethylammonium, hexadecyltrimethylammonium, benzyltrimethylammonium and modified fatty acid dimethylethylammonium; ammonium salts such as chlorates, hydrochlorides, bromates, iodates, fluoroboric acid salts, hydrosulfates, ethyl hydrosulfates, carboxylates and sulfonates; alkali metals such as lithium, sodium, kalium, calcium and magnesium; and chlorates, hydrochlorides, bromates, iodates, fluoroboric acid salts, hydrosulfates, ethyl hydrosulfates, carboxylates and sulfonates of alkaline-earth metals.

These conductivizers can be used alone or in combination. The electron conductivizers and the ionic conductivizers can be combined to stably develop conductivity even when an applied voltage or an environment varies. The content of the electron conductivizers is typically not greater than 100 parts by weight, preferably from 1 to 100 parts by weight, more preferably from 1 to 80 parts by weight, and most preferably from 10 to 50 parts by weight per 100 parts by weight of a resin. The content of the ionic conductivizers is typically from 0.01 to 10 parts by weight, and preferably from 0.05 to 5 parts by weight per 100 parts by weight of a resin. In the present invention, carbon black is preferably used as a conductivizer. The content thereof is preferably from 5 to 30 parts by weight per 100 parts by weight of a resin.

The dispersion of an electroconductive material in a resin material includes a process of wetting the resin material with the electroconductive material and a process of finely dispersing the electroconductive material by a shearing force. In the process of wetting the resin material with the electroconductive material, a method of improving wettability between the resin material and the electroconductive material by maximizing the melt viscosity of the resin and a method of improving compatibility therebetween are used.

In the present invention, the electroconductive material is dispersed in a resin by kneading them while heating them.

The electroconductive material is preferably dispersed at a temperature not less than a Tg of the resin, and more preferably kneaded at a temperature at which the electroconductive material is more melted.

Typically, when an electroconductive material is melted and kneaded with a thermoplastic resin, a high shearing force is applied to an agglutinated electroconductive material to finely break, and the electroconductive material is uniformly dispersed in a melted resin. When the melt viscosity is too low, the wettability further improves, but the shearing force for finely dispersing the decreases. In the present invention, a disperser capable of generating a high shearing force at a low melt viscosity is preferably used.

Specific examples of kneaders generating high shearing force include kneaders using a grindstone mechanism, and kneaders using a kneading disc applying high shearing force in a screw element with a biaxial extruder in the same direction. In addition, a pressure kneader capable of dispersing for along time without applying a high shearing force, and a monoaxial extruder using a specific mixing element can be used.

Methods of improving compatibility between a resin material and an electroconductive material include a method of treating the surface of the electroconductive material and a method of adding a dispersant or an ionic conductivizer to improve wettability therebetween. The surface treatment of the electroconductive material includes a method of treating before dispersing and a method of treating while dispersing. Further, the resin material may be crushed at a room temperature or in a frozen state to have a volume-average particle diameter of from 100 to 1,000 μm, mixed with the electroconductive material, and melted and kneaded.

The belt is preferably formed by an extrusion molding method extruding belt materials from a circular dice or an inflation molding method.

In the present invention, an electron beam is preferably irradiated to an electroconductive material after extruded. An electron beam is irradiated to the melted electroconductive material of the present invention in an atmosphere of an inactive gas (specifically N₂ gas) right after extruded.

The electron beam is preferably irradiated to the electroconductive material in an amount of from 10 to 500 kGy. When less than 10 kGy, the resin is not fully crosslinked. When greater than 500 kGy, the fracture elongation deteriorates, resulting in crack of the belt.

The electrical properties of an intermediate transfer belt right after irradiated with an electron beam were measured in the present invention. A sheet having a size of 50 mm×50 mm was cut from the belt and sandwiched by a copper plate having the same size to measure the electrical properties thereof.

A predetermined voltage (10 V to 1,000 V) having a square-wave pulse period of from 100 to 1000 ms was produced from a high-voltage electric source MODEL 609E-6 from TREK JAPAN Co., Ltd. through a function generator WF1946B from WAVE FACTORY. Then, the current value was measured by an oscilloscope DL1640L from Yokogawa Electric Corporation, and the volume resistivity was determined from a relation between the voltage and the current, and an area and a thickness of the belt.

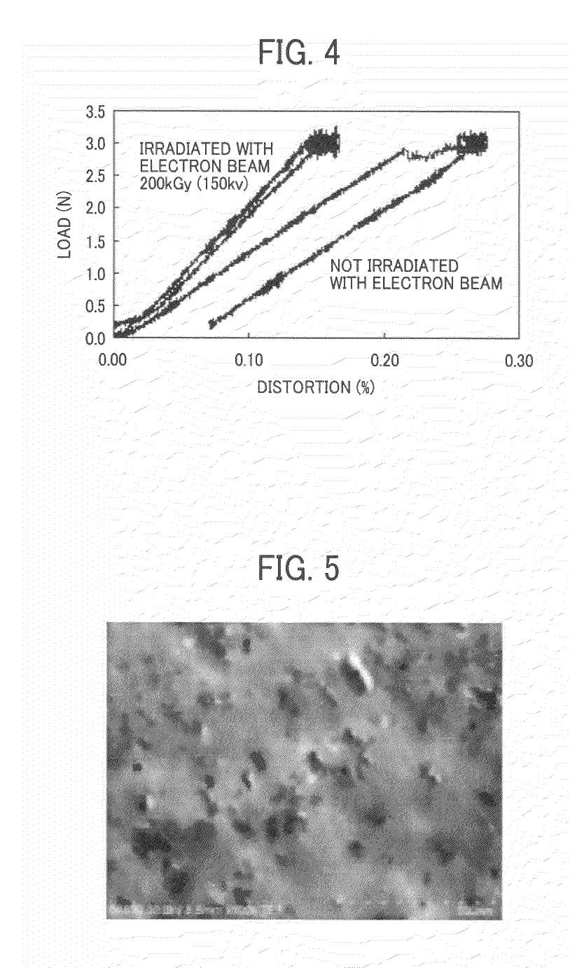

In the present invention, mechanical properties of the belt were measured as follows. A sheet sample was cut by Super Dumbbell Cutter SDMK-1000-D from DUMBBELL CO., LTD. to prepare a dumbbell sample having the shape of a dumbbell specified in JIS K-7127. A tensile strength, an elongation and a fracture elongation of the belt were measured from a distortion-stress curve produced by a precise universal tester Autograph AG-X from Shimadzu Corp. In order to evaluate creep of the belt, the dumbbell sample was elongated to have a tensile force of 3N, which was maintained for 12 hrs, relaxed to form a hysteresis loop, and the size of the hysteresis was measured. FIG. 4 shows hysteresis loops before and after a thermoplastic resin is irradiated with an electron beam, which proves the hysteresis loss is reduced by irradiation of the electron beam.

The basic configuration of the printer of the present invention will be explained.

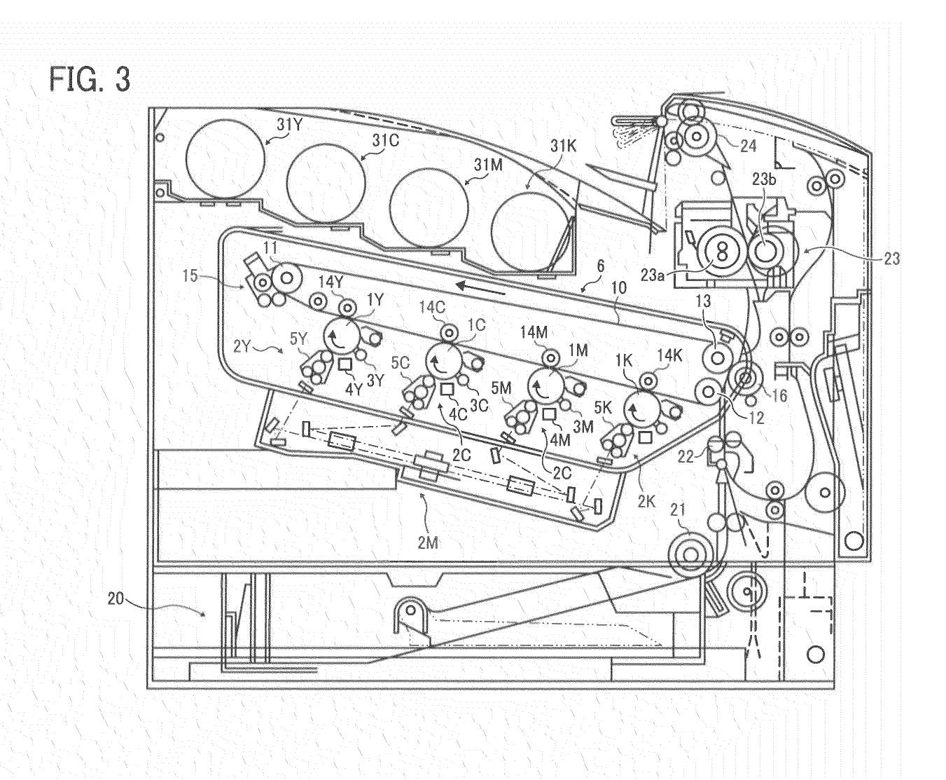

FIG. 3 is a schematic view illustrating an embodiment of the image forming apparatus of the present invention. The image forming apparatus forms a color image with four colors, yellow (Y), cyan (C), magenta (M), and black (K) toners.

First, a basic configuration of a tandem type image forming apparatus will be explained.

The image forming apparatus includes four photoreceptor drums 1Y, 1C, 1M and 1K as electrostatic latent image bearers. They are drum-shaped photoreceptors and may be belt-shaped photoreceptors. Each of the photoreceptor drums 1Y, 1C, 1M and 1K rotates in an arrow direction while contacting an intermediate transfer belt 10. Each of the photoreceptor drums 1Y, 1C, 1M and 1K includes a thin cylindrical electroconductive substrate, a photosensitive layer on the substrate, and a protection layer on the photosensitive layer. An intermediate layer may be formed between the photosensitive layer and the protection layer.

Each irradiator 4 irradiates the surface of the photoreceptor drum 1 to form an electrostatic latent image for each color based on image information for each color. The irradiator 4 uses a laser and may be others including an LED array and an imaging means.

Each image developer 5 contains a color toner fed from a toner bottle 31Y, 31C, 31M or 31K. Each of the toner bottles 31Y, 31C, 31M and 31K is detachable from the image forming apparatus so that it can be exchanged alone. Only the toner bottle 31 may be exchanged when toner ends. Other configurations having lives yet when toner ends can be used as they are.

The intermediate transfer belt 10 is suspended and extended by three suspension and extension rollers 11, 12 and 13, and endlessly travels in an arrow direction. Toner images on the photoreceptor drums 1Y, 1C, 1M and 1K are overlappingly transferred on the intermediate transfer belt 10 by an electrostatic transfer method. The electrostatic transfer method may use a transfer charger, but uses first transfer rollers 14Y, 14C, 14M and 14K in the present invention. Specifically, the first transfer roller 14 is located as a transferer 6 at a part of the backside of the intermediate transfer belt 10 contacting each photoreceptor drum 1. A first transfer nip is formed between the part of the intermediate transfer belt 10 pressed by the first transfer roller 14 and the photoreceptor drum 1. A bias having a positive polarity is applied to the first transfer roller 14 when a toner image is transferred onto the intermediate transfer belt 10. A transfer electric field is formed at the first transfer nip and the toner image on the photoreceptor drum 1 is electrostatically transferred onto the intermediate transfer belt 10. Then, the photoreceptor drum 1 and the intermediate transfer belt 10 preferably contact each other with pressure. The pressure is preferably from 10 to 60 N/m.

Around the intermediate transfer belt 10, a belt cleaner 15 is located to remove a toner remaining on the intermediate transfer belt 10. The belt cleaner 15 collects an unnecessary toner adhering to the surface of the intermediate transfer belt 10 with a fur brush or a cleaning blade. The collected unnecessary toner is transported to an unillustrated waste toner tank by an unillustrated transporter from the belt cleaner 15.

A second transfer roller 16 is located contacting a part of the intermediate transfer belt 10 suspended and extended by a support roller 13. A second transfer nip is formed between the intermediate transfer belt 10 and the second transfer roller 16, which a transfer paper as a recording member is fed to at a predetermined time. The transfer paper is contained in a paper feed cassette 20 below the irradiator 4, and fed to the second transfer nip by a paper feed roller 21, a registration roller 22, etc. The toner images superimposed on the intermediate transfer belt 10 are transferred onto a transfer paper at a time at the second transfer nip. A bias having a positive polarity is applied to the second transfer roller 16 at the second transfer, to form a transfer electric field transferring the toner images superimposed on the intermediate transfer belt 10 are transferred onto the transfer paper.

A heating fixer 23 as a fixing means is located in a paper feed direction at downstream side of the second transfer nip. The heating fixer 23 is formed of a heat roller 23a including a heater and a pressure roller 23b applying a pressure. A transfer paper having passed the second transfer nip is sandwiched between the rollers to receive heat and pressure. Thereby, the toner on the transfer paper is melted and fixed thereon. The transfer paper the toner image is fixed on is discharged by a paper discharge roller 24 onto a paper tray on the image forming apparatus.

A toner for use in the present invention includes at least a resin, a colorant and an additive. The toner can be prepared by pulverization methods or polymerization methods. Other known materials can be used for the toner. The toner preferably has an average particle diameter of from 4 to 8 μm.

Specific examples of the binder resin include styrene polymers such as polystyrene, poly-p-chlorostyrene and polyvinyltoluene; styrene copolymers such as styrene-p-chlorostyrene copolymers, styrene-propylene copolymers, styrene-vinyltoluene copolymers, styrene-vinylnaphthalene copolymers, styrene-methyl acrylate copolymers, styrene-ethyl acrylate copolymers, styrene-butyl acrylate copolymers, styrene-octyl acrylate copolymers, styrene-methyl methacrylate copolymers, styrene-ethyl methacrylate copolymers, styrene-butylmethacrylate copolymers, styrene-methyl α-chloromethacrylate copolymers, styrene-acrylonitrile copolymers, styrene-vinyl methyl ketone copolymers, styrene-butadiene copolymers, styrene-isoprene copolymers, styrene-acrylonitrile-indene copolymers, styrene-maleic acid copolymers and styrene-maleic acid ester copolymers; and other resins such as polymethyl methacrylate, polybutylmethacrylate, polyvinyl chloride, polyvinyl acetate, polyethylene, polypropylene, polyesters, epoxy resins, epoxy polyol resins, polyurethane resins, polyamide resins, polyvinyl butyral resins, acrylic resins, rosin, modified rosins, terpene resins, aliphatic or alicyclic hydrocarbon resins, aromatic petroleum resins, chlorinated paraffin, paraffin waxes, etc. Incompatible combinations include combinations of resins having properties largely different from each other such as styrene-butylacrylate copolymers and polyesters, epoxy resins or epoxy polyol resins; resins having molecular weight distributions largely different from each other; and resins having substituents largely different from each other.

The epoxy polyol resins include (A) polyol produced by a reaction among (i) an epoxy resin such as a bisphenol A epoxy resin, (ii) a bivalent phenol with an adduct of alkylene oxide or glycidyl ether thereof and (iii) a compound having an active hydrogen group reactable with an epoxy group in its molecule; and (B) polyol produced by a reaction among (i) an epoxy resin, (ii) a bivalent phenol and (iii) a compound having an active hydrogen group reactable with an epoxy group in its molecule.

Specific examples of the colorant for use in the present invention include any known dyes and pigments such as carbon black, Nigrosine dyes, black iron oxide, NAPHTHOL YELLOW S, HANSA YELLOW (10G, 5G and G), Cadmium Yellow, yellow iron oxide, loess, chrome yellow, Titan Yellow, polyazo yellow, Oil Yellow, HANSA YELLOW (GR, A, RN and R), Pigment Yellow L, BENZIDINE YELLOW (G and GR), PERMANENT YELLOW (NCG), VULCAN FAST YELLOW (5G and R), Tartrazine Lake, Quinoline Yellow Lake, ANTHRAZANE YELLOW BGL, isoindolinone yellow, red iron oxide, red lead, orange lead, cadmium red, cadmium mercury red, antimony orange, Permanent Red 4R, Para Red, Fire Red, p-chloro-o-nitroaniline red, Lithol Fast Scarlet G, Brilliant Fast Scarlet, Brilliant Carmine BS, PERMANENT RED (F2R, F4R, FRL, FRLL and F4RH), Fast Scarlet VD, VULCAN FAST RUBINE B, Brilliant Scarlet G, LITHOL RUBINE GX, Permanent Red FSR, Brilliant Carmine 6B, Pigment Scarlet 3B, Bordeaux 5B, Toluidine Maroon, PERMANENT BORDEAUX F2K, HELIO BORDEAUX BL, Bordeaux 10B, BON MAROON LIGHT, BON MAROON MEDIUM, Eosin Lake, Rhodamine Lake B, Rhodamine Lake Y, Alizarine Lake, Thioindigo Red B, Thioindigo Maroon, Oil Red, Quinacridone Red, Pyrazolone Red, polyazo red, Chrome Vermilion, Benzidine Orange, perynone orange, Oil Orange, cobalt blue, cerulean blue, Alkali Blue Lake, Peacock Blue Lake, Victoria Blue Lake, metal-free Phthalocyanine Blue, Phthalocyanine Blue, Fast Sky Blue, INDANTHRENE BLUE (RS and BC) Indigo, ultramarine, Prussianblue, Anthraquinone Blue, Fast Violet B, Methyl Violet Lake, cobalt violet, manganese violet, dioxane violet, Anthraquinone Violet, Chrome Green, zinc green, chromiumoxide, viridian, emerald green, Pigment Green B, Naphthol Green B, Green Gold, Acid Green Lake, Malachite Green Lake, Phthalocyanine Green, Anthraquinone Green, titanium oxide, zinc oxide, lithopone and their mixtures. The content thereof is typically from 0.1 to 50 parts by weight per 100 parts by weight of the binder resin.

The toner may include a charge controlling agent if desired. Specific examples of the charge controlling agent include, but are not limited to, known charge controlling agents such as Nigrosine dyes, triphenylmethane dyes, metal complex dyes including chromium, chelate compounds of molybdic acid, Rhodamine dyes, alkoxyamines, quaternary ammonium salts (including fluorine-modified quaternary ammonium salts), alkylamides, phosphor and compounds including phosphor, tungsten and compounds including tungsten, fluorine-containing activators, metal salts of salicylic acid, salicylic acid derivatives, copper phthalocyanine, perylene, quinacridone, azo pigments and polymers having a functional group such as a sulfonate group, a carboxyl group, a quaternary ammonium group, etc.

In the present invention, the toner is preferably coated with an external additive to have appropriate fluidity, chargeability, cleanability and stress resistance against contact members such as photoreceptor charger. The surface of the toner is preferably coated with the external additive by 5 to 99%, and more preferably by 5 to 99%.

Specific examples of the external additive include metal oxides such as aluminum oxide, titanium oxide, strontium titanate, cerium oxide, magnesium oxide, chrome oxide, tin oxide and zinc oxide; nitrides such as silicon nitride; metal salts such as calcium sulfate, barium sulfate and calcium carbonate; metal salts of fatty acid such as zinc stearate and calcium stearate; carbon black; and silica. The toner preferably includes the external additive in an amount of from 0.01 to 10 parts by weight, and more preferably from 0.01 to 10 parts by weight. These can be used alone or in combination. They are preferably hydrophobized.

Inorganic particulate materials for use in the present invention are preferably at least one of silica, alumina, titania and their multiple oxides to improve charge stability, developability, fluidity and preservability of the resultant toner. Particularly, silica is most preferably used. Both of dry (fumed) silica produced by steam phase oxidization of halide silicon or alkoxide and wet silica produced from alkoxide liquid glass can be used. The dry silica including less silanol groups and production residues such as Na₂O and SO₃ is more preferably used. A complex fine powder formed of silica and other metal oxides can be obtained when the dry silica is produced by using other halide metals such as aluminum chloride and titanium chloride with halide silicon.

The inorganic particulate materials for use in the present invention preferably have a particle diameter of from 5 to 200 nm.

Treatment agents such as silicone varnishes, various modified silicone varnishes, silicone oils, various modified silicone oils, silane coupling agents, silane coupling agents having a functional group, organic silicon compounds and organic titanium compounds can be sued alone or in combination for the external additives (inorganic particulate materials) for use in the present invention for the purpose of hydrophobization, charge control, etc. The inorganic fine powder is preferably treated with silicone oil for the resultant toner to have high charge amount, low consumed amount and high transferability.

The external additives are mixed with a mother toner by a mixer and mechanically attached to the surface thereof.

Specific examples of the mixers include HENSCHEL MIXER from Mitsui Mining Co., Ltd.; SUPER MIXER from KAWATA MFG Co., Ltd.; RIBOCONE from OKAWARA MFG CO., LTD.; NAUTER MIXER, TURBULA MIXER and CYCLOMIX from Hosokawa Micron Corp.; SPIRALPIN MIXER from Pacific Machinery & Engineering Co., Ltd; and LOEDIGE from MATSUBO Corp.

Having generally described this invention, further understanding can be obtained by reference to certain specific examples which are provided herein for the purpose of illustration only and are not intended to be limiting. In the descriptions in the following examples, the numbers represent weight ratios in parts, unless otherwise specified.

### EXAMPLES

### Example 1

Eight parts of electroconductive carbon black from Degussa AG and 100 parts of a polypropylene (PP) resin having a melting point of 169° C. (NOVATEC FA3EB from Japan Polypropylene Corp. were mixed and kneaded by a kneader at 150° C. for 30 min, the carbon black was further dispersed by a two-roll mill for 30 min, and pelletized by a pelletizer to prepare an electroconductive pellet. The pellet was extruded to prepare a seamless belt having a thickness of 100 μm.

The dispersed state of the carbon black in the seamless belt was observed by a STEM S-4800 from Hitachi High-Technologies Corp. to find the carbon black was uniformly dispersed as shown in FIG. 5.

The electrical properties thereof were measured by HIRESTA MCP-HT450 from Mitsubishi Chemical Analytech Co., Ltd. to find Log(ρv 200) was 7.3 and Log(ρv 10)−Log(ρv 1000) was 1.4.

An electron beam having an accelerating voltage of 300 kV and 30 kGy was irradiated to the belt by an electron beam irradiator EBC-300-60 from NHV Corp. at 55° C.

### Example 2

Eight parts of electroconductive carbon black from Degussa AG and 100 parts of a polypropylene (PP) resin having a melting point of 169° C. (NOVATEC FA3EB from Japan Polypropylene Corp. were mixed and kneaded by a kneader at 150° C. for 30 min, the carbon black was further dispersed by a two-roll mill for 30 min, and pelletized by a pelletizer to prepare an electroconductive pellet. The pellet was extruded to prepare a seamless belt having a thickness of 100 μm.

The dispersed state of the carbon black in the seamless belt was observed by a STEM S-4800 from Hitachi High-Technologies Corp. to find the carbon black was uniformly dispersed as it was in Example 1.

An electron beam having an accelerating voltage of 300 kV and 180 kGy was irradiated to the belt by an electron beam irradiator EBC-300-60 from NHV Corp. at 55° C.

### Example 3

Eight parts of electroconductive carbon black from Degussa AG and 100 parts of a polypropylene (PP) resin having a melting point of 169° C. (NOVATEC FA3EB from Japan Polypropylene Corp. were mixed and kneaded by a kneader at 150° C. for 30 min, the carbon black was further dispersed by a two-roll mill for 30 min, and pelletized by a pelletizer to prepare an electroconductive pellet. The pellet was extruded to prepare a seamless belt having a thickness of 100 μm.

The dispersed state of the carbon black in the seamless belt was observed by a STEM S-4800 from Hitachi High-Technologies Corp. to find the carbon black was uniformly dispersed as it was in Example 2.

An electron beam having an accelerating voltage of 300 kV and 500 kGy was irradiated to the belt by an electron beam irradiator EBC-300-60 from NHV Corp. at 55° C.

### Example 4

Eight parts of electroconductive carbon black from Degussa AG, 1 part of an ionic conductivizer (tetrabutylammonium hydrogen sulfate from Koei Chemical Co., Ltd.) and 100 parts of a fluorine-containing resin (PVDF KF#1000; NFR=8 g/10 min from KUREHA CORP.) were mixed and kneaded by a kneader at 150° C. for 80 min, the carbon black was further dispersed by a two-roll mill for 60 min, and pelletized by a pelletizer to prepare an electroconductive pellet. The pellet was extruded to prepare a seamless belt having a thickness of 100 μm.

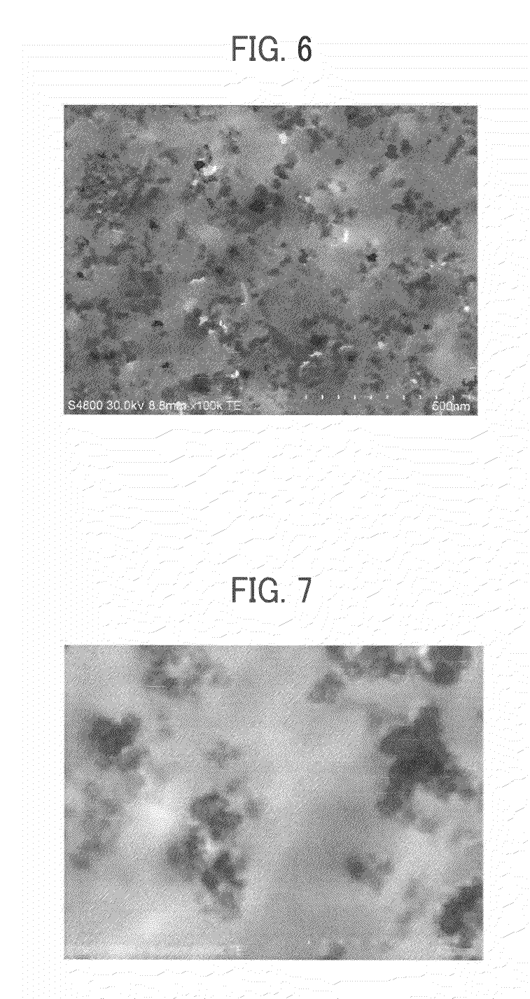

The dispersed state of the carbon black in the seamless belt was observed by a STEM S-4800 from Hitachi High-Technologies Corp. to find the carbon black was uniformly dispersed as shown in FIG. 6.

The electrical properties thereof were measured by HIRESTA MCP-HT450 from Mitsubishi Chemical Analytech Co., Ltd. to find Log(ρv 200) was 8.4 and Log(ρv 10)−Log(ρv 1000) was 1.2.

An electron beam having an accelerating voltage of 300 kV and 30 kGy was irradiated to the belt by an electron beam irradiator EBC-300-60 from NHV Corp. at 55° C.

### Example 5

Eight parts of electroconductive carbon black from Degussa AG, 1 part of an ionic conductivizer (tetrabutylammonium hydrogen sulfate from Koei Chemical Co., Ltd.) and 100 parts of a fluorine-containing resin (PVDF KF#1000; NFR=8 g/10 min from KUREHA CORP.) were mixed and kneaded by a kneader at 150° C. for 80 min, the carbon black was further dispersed by a two-roll mill for 60 min, and pelletized by a pelletizer to prepare an electroconductive pellet. The pellet was extruded to prepare a seamless belt having a thickness of 100 μm.

The dispersed state of the carbon black in the seamless belt was observed by a STEM S-4800 from Hitachi High-Technologies Corp. to find the carbon black was uniformly dispersed as it was in Example 4.

The electrical properties thereof were measured by HIRESTA MCP-HT450 from Mitsubishi Chemical Analytech Co., Ltd. to find Log(ρv 200) was 8.4 and Log(ρv 10)−Log(ρv 1000) was 1.2.

An electron beam having an accelerating voltage of 300 kV and 180 kGy was irradiated to the belt by an electron beam irradiator EBC-300-60 from NHV Corp. at 80° C.

### Example 6

Eight parts of electroconductive carbon black from Degussa AG, 1 part of an ionic conductivizer (tetrabutylammonium hydrogen sulfate from Koei Chemical Co., Ltd.) and 100 parts of a fluorine-containing resin (PVDF KF#1000; NFR=8 g/10 min from KUREHA CORP.) were mixed and kneaded by a kneader at 150° C. for 80 min, the carbon black was further dispersed by a two-roll mill for 60 min, and pelletized by a pelletizer to prepare an electroconductive pellet. The pellet was extruded to prepare a seamless belt having a thickness of 100 μm.

The dispersed state of the carbon black in the seamless belt was observed by a STEM S-4800 from Hitachi High-Technologies Corp. to find the carbon black was uniformly dispersed as it was in Example 5.

The electrical properties thereof were measured by HIRESTA MCP-HT450 from Mitsubishi Chemical Analytech Co., Ltd. to find Log(ρv 200) was 8.4 and Log(ρv 10)−Log(ρv 1000) was 1.2.

An electron beam having an accelerating voltage of 300 kV and 180 kGy was irradiated by an electron beam irradiator EBC-300-60 from NHV Corp. at 55° C.

### Example 7

Eight parts of electroconductive carbon black from Degussa AG, 1 part of an ionic conductivizer (tetrabutylammonium hydrogen sulfate from Koei Chemical Co., Ltd.), 0.5 parts of a crosslinker triallylisocyanurate (TAIC from NIPPON KAYAKU Co., Ltd.) and 100 parts of a fluorine-containing resin (PVDF KF#1000; NFR=8 g/10 min from KUREHA CORP.) were mixed and kneaded by a kneader at 150° C. for 80 min, the carbon black was further dispersed by a two-roll mill for 60 min, and pelletized by a pelletizer to prepare an electroconductive pellet. The pellet was extruded to prepare a seamless belt having a thickness of 100 μm.

The dispersed state of the carbon black in the seamless belt was observed by a STEM S-4800 from Hitachi High-Technologies Corp. to find the carbon black was uniformly dispersed as it was in Example 3.

The electrical properties thereof were measured by HIRESTA MCP-HT450 from Mitsubishi Chemical Analytech Co., Ltd. to find Log(ρv 200) was 8.4 and Log(ρv 10)−Log(ρv 1000) was 1.2.

An electron beam having an accelerating voltage of 300 kV and 30 kGy was irradiated to the belt by an electron beam irradiator EBC-300-60 from NHV Corp.

### Example 8

Eight parts of electroconductive carbon black from Degussa AG, 1 part of an ionic conductivizer (tetrabutylammonium hydrogen sulfate from Koei Chemical Co., Ltd.), 0.5 parts of a crosslinker triallylisocyanurate (TAIC from NIPPON KAYAKU Co., Ltd.) and 100 parts of a fluorine-containing resin (PVDF KF#1000; NFR=8 g/10 min from KUREHA CORP.) were mixed and kneaded by a kneader at 150° C. for 80 min, the carbon black was further dispersed by a two-roll mill for 60 min, and pelletized by a pelletizer to prepare an electroconductive pellet. The pellet was extruded to prepare a seamless belt having a thickness of 100 μm.

The dispersed state of the carbon black in the seamless belt was observed by a STEM S-4800 from Hitachi High-Technologies Corp. to find the carbon black was uniformly dispersed as it was in Example 7.

The electrical properties thereof were measured by HIRESTA MCP-HT450 from Mitsubishi Chemical Analytech Co., Ltd. to find Log(ρv 200) was 8.4 and Log(ρv 10)−Log(ρv 1000) was 1.2.

An electron beam having an accelerating voltage of 300 kV and 180 kGy was irradiated to the belt by an electron beam irradiator EBC-300-60 from NHV Corp.

### Comparative Example 1

Eight parts of electroconductive carbon black from Degussa AG and 100 parts of a polypropylene (PP) resin having a melting point of 169° C. (NOVATEC FA3EB from Japan Polypropylene Corp. were mixed and kneaded by a kneader at 150° C. for 30 min, the carbon black was further dispersed by a two-roll mill for 30 min, and pelletized by a pelletizer to prepare an electroconductive pellet. The pellet was extruded to prepare a seamless belt having a thickness of 100 μm.

The dispersed state of the carbon black in the seamless belt was observed by a STEM S-4800 from Hitachi High-Technologies Corp. to find the carbon black was uniformly dispersed as it was in Example 1.

The electrical properties thereof were measured by HIRESTA MCP-HT450 from Mitsubishi Chemical Analytech Co., Ltd. to find Log(ρv 200) was 7.3 and Log(ρv 10)−Log(ρv 1000) was 1.4.

An electron beam was not irradiated to the belt.

### Comparative Example 2

Eight parts of electroconductive carbon black from Degussa AG and 100 parts of a polypropylene (PP) resin having a melting point of 169° C. (NOVATEC FA3EB from Japan Polypropylene Corp. were mixed and kneaded by a kneader at 150° C. for 30 min, the carbon black was further dispersed by a two-roll mill for 30 min, and pelletized by a pelletizer to prepare an electroconductive pellet. The pellet was extruded to prepare a seamless belt having a thickness of 100 μm.

The dispersed state of the carbon black in the seamless belt was observed by a STEM S-4800 from Hitachi High-Technologies Corp. to find the carbon black was uniformly dispersed as it was in Comparative Example 1.

An electron beam having an accelerating voltage of 300 kV and 640 kGy was irradiated to the belt by an electron beam irradiator EBC-300-60 from NHV Corp.

### Comparative Example 3

Eight parts of electroconductive carbon black from Degussa AG and 100 parts of a polypropylene (PP) resin having a melting point of 169° C. (NOVATEC FA3EB from Japan Polypropylene Corp. were mixed and kneaded by a kneader at 150° C. for 10 min, the carbon black was further dispersed by a two-roll mill for 15 min, and pelletized by a pelletizer to prepare an electroconductive pellet. The pellet was extruded to prepare a seamless belt having a thickness of 100 μm.

The dispersed state of the carbon black in the seamless belt was observed by a STEM S-4800 from Hitachi High-Technologies Corp. to find the carbon black was nonuniformly dispersed as shown in FIG. 7.

The electrical properties thereof were measured by HIRESTA MCP-HT450 from Mitsubishi Chemical Analytech Co., Ltd. to find Log(ρv 200) was 11.6 and Log(ρv 10)−Log(ρv 1000) was 2.4.

An electron beam having an accelerating voltage of 300 kV and 180 kGy was irradiated by an electron beam irradiator EBC-300-60 from NHV Corp. at 55° C.

Each of the intermediate transfer belts prepared in Examples 1 to 8 and Comparative Examples 1 to 3 was installed in marketed printer IPSiO SP C220 from Ricoh Company, Ltd. to evaluate image quality. The results were shown in Table 1.

### (Image Quality [Thin Line Images])

Thin line images were produced on a plain paper T6200 from Ricoh Company, Ltd. at an interval of 200 μm to visually observe the images through an optical microscope.

No disturbed images: Very good:

Toner scattered but no disturbed images: Good

Toner scattered and images were disturbed: unusable

### (Creep)

A sheet having a size of 20 mm×50 mm cut from the belt was wounded around s SUS roller having a diameter of 20 mm, and left at 50° C. and 90% Rh for 48 hrs to evaluate curl (distance of arch/50 mm×100 [%]) at room temperature.

Not less than 75%: Very good

Not less than 65% and less than 75%: Good

Not less than 50% and less than 65%: Usable

Less than 50%: Unusable

When not less than 65%, images without uneven image density or defective images were produced.

### (Crack)

After 10,000 images were produced on plain papers T6200 from Ricoh Company, Ltd. by marketed printer IPSiO SP C220 from Ricoh Company, Ltd., the end of the belt was visually observed.

No cracks: Very good

Slight cracks: Usable

Cracks: Unusable

TABLE 1

| | Ex. 1 | Ex. 2 | Ex. 3 | Ex. 4 | Ex. 5 | Ex. 6 | Ex. 7 | Ex. 8 |
|---|---|---|---|---|---|---|---|---|
| Resin | PP | PP | PP | PVDF | PVDF | PVDF | PVDF | PVDF |
| Irradiance level | 30 | 180 | 300 | 100 | 200 | 300 | 30 | 180 |
| Log (ρv 10)-Log (ρv 1000) | 1.4 | 1.4 | 1.4 | 1.2 | 1.2 | 1.2 | 1.2 | 1.2 |
| crosslinker | None | None | None | None | None | None | TAIC | TAIC |
| Image quality | Very | Very | Very | Very | Very | Very | Very | Very |
| | good | good | good | good | good | good | good | good |
| Creep | Usable | Very | Very | Usable | Good | Good | Very | Very |
| | | good | good | | | | good | good |
| Crack | Very | Very | Usable | Very | Very | Very | Very | Very |
| | good | good | | good | good | good | good | good |

| | Com. Ex. 1 | Com. Ex. 2 | Com. Ex. 3 |
|---|---|---|---|
| Resin | PP | PP | PP |
| Irradiance level | 0 | 640 | 30 |
| Log (ρv 10)-Log (ρv 1000) | 1.2 | 1.2 | 2.4 |
| crosslinker | None | None | None |
| Image quality | Very good | Very good | Unusable |
| Creep | Unusable | Very good | Very good |
| Crack | Very good | Unusable | Very good |

This application claims priority and contains subject matter related to Japanese Patent Application No. 2010-045687 filed on Mar. 2, 2010, the entire contents of which are hereby incorporated by reference.

Having now fully described the invention, it will be apparent to one of ordinary skill in the art that many changes and modifications can be made thereto without departing from the spirit and scope of the invention as set forth therein.

1. A belt member, comprising:
a crosslinked product of a thermoplastic resin; and
an electroconductive particulate material,
wherein the belt member satisfies the following formulae (i) and (ii):
6≦log(ρv200)≦10 (i)
0≦log(ρv10)−log(ρv1,000)≦2 (ii)
wherein ρv200, ρv10, and ρv1,000 represent volume resistivities of the belt member when biases of 200 V, 10 V and 1,000 V, respectively are applied to the belt member.

2. The belt member of claim 1, wherein the crosslinked product is obtained by a process comprising:
melting the thermoplastic resin to form a melted resin;
extruding the melted resin to prepare an extruded resin; and
irradiating the extruded resin with an electron beam.

3. The belt member of claim 1, wherein the electroconductive particulate material has an average primary particle diameter of from 5 to 50 nm.

4. The belt member of claim 1, wherein the electroconductive particulate material is a metal or a metal oxide selected from the group consisting of carbon black, graphite, natural graphite, artificial graphite, tin oxide, titanium oxide, zinc oxide, nickel, and copper.

5. An intermediate transfer belt comprising:
an electrostatic latent image former configured to form an electrostatic latent image on an image bearer;
an image developer configured to develop the electrostatic latent image with a toner to form a toner image on the image bearer;
a first transferer configured to transfer the toner image on the image bearer onto the intermediate transfer belt;
a second transferer configured to transfer the toner image on the intermediate transfer belt onto a recording medium;
a fixer configured to fix the toner image on the recording medium; and
the belt member according to claim 1.

6. An image forming method, comprising:
forming an electrostatic latent image on an image bearer;
developing the electrostatic latent image with a toner to form a toner image on the image bearer;
transferring the toner image on the image bearer onto the intermediate transfer belt according to claim 5;
transferring the toner image on the intermediate transfer belt onto a recording medium; and
fixing the toner image on the recording medium.

7. An image forming apparatus, comprising:
an electrostatic latent image former configured to form an electrostatic latent image on an image bearer;
an image developer configured to develop the electrostatic latent image with a toner to form a toner image on the image bearer;
a first transferer configured to transfer the toner image on the image bearer onto the intermediate transfer belt according to claim 5;
a second transferer configured to transfer the toner image on the intermediate transfer belt onto a recording medium; and
a fixer configured to fix the toner image on the recording medium.

8. A method of preparing a belt member for intermediate transfer, comprising:
melting and kneading materials comprising a thermoplastic resin and an electroconductive particulate;
extruding the melted and kneaded materials to prepare an extruded material; and
irradiating the extruded material with an electron beam,
wherein the belt member satisfies the following formulae (i) and (ii):
6≦log(ρv200)≦10 (i)
0≦log(ρv10)−log(ρv1,000)≦2 (ii)
wherein ρv200, ρv10, and ρv1,000 represent volume resistivities of the belt member when biases of 200 V, 10 V and 1,000 V, respectively are applied to the belt.

9. The method of claim 8, wherein the materials further comprise at least one crosslinker selected from the group consisting of triallylisocyanurate, triallylcyanurate, trimethallylisocyanurate, and diallylmonoglycidylisocyanurate.

10. The method of claim 8, wherein the electron beam has a dose of from 10 kGy to 500 kGy.

11. The method of claim 8, wherein the electron beam is radiated at a temperature not less than a glass transition temperature of the thermoplastic resin.
